(19) United States
(12) Patent Application Publication
(10) Pub. No.: US 2026/0031772 A1
(43) Pub. Date: Jan. 29, 2026

(54) AMPLIFIER HAVING DIFFERENT SECTIONS WITH A CLICKING CONTROL KNOB

(71) Applicant: Third Man Hardware LLC, Nashville, TN (US)

(72) Inventor: John Anthony White, Nashville, TN (US)

(73) Assignee: Third Man Hardware LLC, Nashville, TN (US)

(21) Appl. No.: 18/781,772

(22) Filed: Jul. 23, 2024

(51) Int. Cl. H03F 3/183; G10K 15/08; H04R 3/04

(52) U.S. Cl. CPC H03F 3/183; G10K 15/08; H04R 3/04; H03F 2200/03; H04R 2430/01

(57) ABSTRACT

An amplifier may have a plurality of control sections in which each control section has a plurality of control knobs and a first control knob in each control section that has an off position. The first control knob in each control section clicks (audibly and/or mechanically) as it enters or exists the off position.

### FIELD

The disclosure relates generally to an amplifier and in particular to an amplifier with multiple section in which a first control knob in each section clicks when it enters or exits an OFF position.

### BACKGROUND

An amplifier has been in existence for a very long time. The amplifier may be used to amplify the sound/tones generated by various musical instruments such as a keyboard or a guitar. For an electric guitar, the guitar has pickups that sense the metal guitar strings vibrating and that generate electrical signals based on the vibration of the metal guitar strings and the amplifier amplifies those electrical signals. Amplifiers exist for both electric guitars and acoustic guitars. Each amplifier has one or more control knobs that are used to control the amplification of the sound. Often, amplifiers have sound effects to change the sound output from the amplifier and the sound effects also may be controlled by the one or more control knobs.

The configuration and function of the series of control knobs on an amplifier have varied greatly. In the past, at least a power knob may have “0”/off position. Furthermore, some of the old power knobs may click when turned. In more modern amplifiers, manufacturers have moved away from control knobs with a “0”/off position especially for control knobs for each different section of the amplifier. Thus, it is desirable to provide an amplifier with different sections with clickable control knobs and it is to this end that the disclosure is directed.

### BRIEF DESCRIPTION OF THE DRAWINGS

FIG. 1 is an amplifier having one or more sections and each section has a clickable control knob;

FIGS. 2A and 2B are a top view and a side view of an example of an amplifier control knob;

FIG. 2C is a top view of an example of an amplifier control knob; and

FIG. 2D is a top view of an example of a clicking control knob with an OFF position.

### DETAILED DESCRIPTION OF ONE OR MORE EMBODIMENTS

The disclosure is particularly applicable to an amplifier that has one or more different sections including tremolo and reverb and each section having a clickable control knob and it is in this context that the disclosure will be described. A guitar amplifier embodiment is described below for illustration purposes. It will be appreciated, however, that the amplifier may have different sections that each have a clickable control knob and the amplifier may be used for various different musical instruments (guitars, bass guitars, keyboards and the like) that are all within the scope of this disclosure.

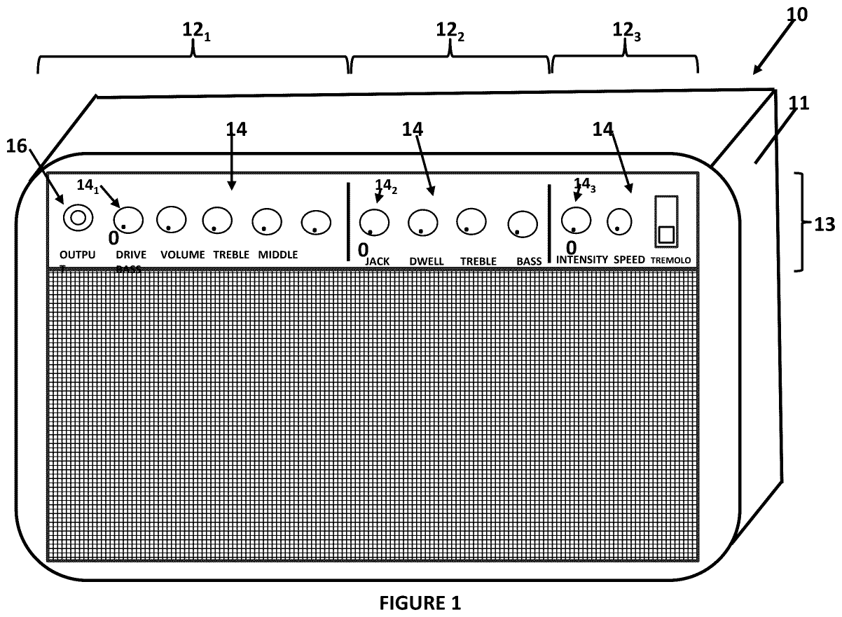

FIG. 1 is an amplifier 10 having one or more sections 12₁, 12₂ and 12₃ with each section controlling a different function/operation of the amplifier. The amplifier may have a preamplifier first stage and a second amplifier stage. A relatively weak signal goes from the musical instrument into the preamplifier first stage that processes the relatively weak signal from the musical instrument and the processed signal is handed to the second stage, which boosts the relatively weak signal into a strong signal which then is converted into the sound that comes out of the speakers. A user can control the level or strength of the signal sent through the preamplifier first stage and this control is called “gain” that may be labeled as “drive”. Gain/Drive can be thought of as the input volume to the preamplifier stage (gain adjustments can produce changes in overall volume although it is more of a tone control than a volume control.) In other words, the gain/drive setting determines how hard a user is driving the preamp section of the amplifier. Thus, setting the gain/drive control sets the level of distortion in your tone, regardless of how loud the final volume of the amplifier is set.

The amplifier 10 in FIG. 1 has typical and known circuits (analog and/or digital) or electronic circuits/circuitry and one or more speakers inside of an amplifier housing/body 11. The sounds generated by the one or more speakers is adjusted/controlled by the circuits is a well known manner. For example, sound effects or the overall sound characteristics (frequencies, volume, etc.) may be controlled in a well understood manner. The amplifier also may have a control portion 13 on the body 11 on which each of the controls and inputs to the amplifier are located.

Thus, the amplifier may have one or more speakers and electronics/circuits (not shown in FIG. 1 but well understood in the art) whose sound amplification functions and operations are controlled by two or more sections 12 of the control portion 13 and that generate and output the sound based on a signal input from a musical instrument. In the example embodiment in FIG. 1, the amplifier may have three control sections 12₁, 12₂ and 12₃, but the disclosure is not limited to any particular number of control sections as long as the amplifier has at least two control sections.

In one embodiment of a guitar amplifier shown in FIG. 1, the first section 12₁ may be a main normal operation control section that controls the overall “normal” operation of the amplifier, the second control section 12₂ may be a reverb control section that controls the reverb operations of the amplifier and the third control section 12₃ may be a tremolo control section that controls the tremolo function of the amplifier. The reverb control section and tremolo control section control distortion sound effects of the amplifier that change sound output from the amplifier, such as a reverb sound effect or a tremolo sound effect.

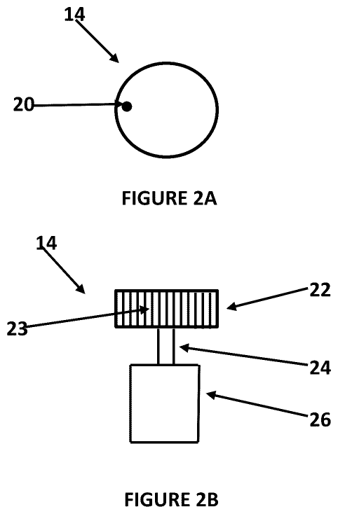

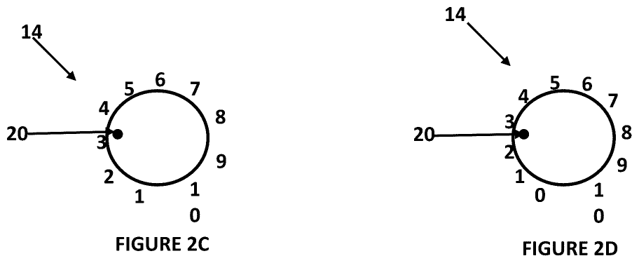

As shown in FIG. 1, each control section 12₁, 12₂ and 12₃ may have a plurality of control knobs 14 that allow a user to adjust one or more characteristics of the sound generated and output by the amplifier 10. For purposes of illustration and clarity in FIG. 1, each control knob 14 is shown as a circle, but each control knob may be implemented as shown in FIGS. 2A-2D as described below.

FIGS. 2A and 2B are a top view and a side view of an example of an amplifier control knob 14. Each control knob 14 may have an indicator 20, such as a black dot in the examples in this disclosure, that aligns with different level values (level 1 to level 10 for example or level 0 to level 10 for certain control knob in each section as discussed below) for the variable, such as drive or volume, to indicate a level for the variable. For example, the volume control knob may indicate volume level 5 indicating a middle level of volume was selected by the user. The different levels for each variable controlled by each control knob are not shown in FIG. 1 for clarity, but each control knob 14 would have a displayed indicia for each level on the control knob or on the amplifier body as shown in FIGS. 2C and 2D. The control knob 14 may rotate so that a position of the indicator 20 may be changed to adjust the variable value.

As shown in FIG. 2B, each control knob 14 may have a top portion 22 that has the indicator 20 on its top surface. The top portion 22 may have knurling pattern or a knurled surface 23 on its edges that provides a user with a better grip on each control knob. Each control knob 14 also may have a shaft 24 that mechanically connects the top portion 22 to a device 26 that, in response to a rotation of the top portion 22, changes its signal. For example, the device 26 may be a potentiometer or a digital encoder or any other device whose value/signal changes based on the rotation of control knob. For the control knobs in each section that have an off/0 position and click when the control knob enters or exits the off/0 position (as described below in more detail), the device 26 may be a potentiometer or a digital encoder or any other device whose value/signal changes based on the rotation of control knob and that clicks when entering or exiting the off/0 position.

FIG. 2C is a top view of an example of an amplifier control knob 14 with the indicator 20 in which level values (values 1-10) may appear on the control portion 13 or body 11 of the amplifier. This control knob 14 does not have an off/0 position and do not click (mechanically and audibly). This type of amplifier control knob 14 is used for most of the control knobs of the amplifier 10. In the amplifier 10 shown in FIG. 1, all of the control knobs 14 uses the control knob 14 shown in FIG. 2C except the first control knob 14₁, 14₂, 14₃ in each control section that uses the control knob shown in FIG. 2D.

FIG. 2D is a top view of an example of a clicking control knob 14 (14₁, 14₂, 14₃ in the example shown in FIG. 1 for each of the three control sections 12₁, 12₂, 12₃) that may be used as the first/leftmost control knob in each section of the amplifier. As shown in FIG. 2D, there is an off position (the “0” value not present in FIG. 2C) in which the control knob 14 in FIG. 2D clicks (mechanically and/or audibly) when entering or exiting the off position. In various embodiments, this clicking control knob 14 may be a leftmost/first control knob for each control section 12₁, 12₂, 12₃ of the amplifier 10.

Returning to FIG. 1, the normal operation section 12₁ may have an output 16 into which the musical instrument (not shown in FIG. 1) may be plugged in. For an amplifier 10 for a different type of musical instrument, the output may have a different configuration that is within the scope of this disclosure. The normal operation section may have a drive control knob to adjust the drive at the preamplifier stage as discussed above, a volume control knob to adjust the overall volume of the sound output from the amplifier, a treble control knob to adjust a higher frequency range of sounds output from the amplifier, a middle control knob to adjust a middle frequency range of sounds output from the amplifier and a bass control knob to adjust a lower frequency range of sounds output from the amplifier. In accordance with the disclosure, a first control knob 14₁ in this section may have a “0”/off position (shown in FIG. 2D) and the control knob may click (mechanically and/or audibly) when the control knob is turned so that the indicator is at the “0” position (indicating that the control knob is in the OFF position) or when the control knob is OFF and is turned to a level in the ON position (levels 1-10 shown in FIG. 2D) so that the user gets feedback when a first control knob in each control section is turned to the OFF position or turned to level from the OFF position (in other words when the first control knob enters the off state/position or exits the off state/position).

The reverb section 12₂ may similarly have a set of control knobs 14 that may include a jack control knob that controls the reverb functions of the amplifier and a dwell control knob that allows the user to control the drive of the reverb so that the dwell control affects the decay time of the reverb, allowing the user to shorten it. The dwell control, balanced with the normal reverb control that sits at the output of the circuit, allows a far greater range of reverb sounds to be accessed with very little effort. The reverb section 12₂ may also include a treble control knob to control the higher level frequencies of the reverb and a bass control knob to control the lower frequencies of the reverb. The control knobs of the reverb section have the same structure, indicator, levels, etc. as described above and a first reverb section knob 14₂ may include an OFF position/‘V’ level that also clicks as described above.

The tremolo control section 12₃ also has a plurality of control knobs 14 including a first control knob 14₃ that controls intensity (a variation in volume/amplitude of the sound generated by the amplifier to set the limit of volume loss of the effect, from subtle variation to completely deadening the signal), a second control knob that controls speed to sync the tremolo effect to the tempo of a song and a tremolo slide switch that switches between mono and stereo tremolo. Like the two other sections, the first control knob 14₃ has a 0/off position and clicks into and out of that 0/off position.

The first control knob 14₁, 14₂, 14₃ of each section 12₁, 12₂, 12₃ have the 0/off position and each knob clicks into that 0/off position and then clicks as the knob is turned out of the 0/off position. These first control knobs in each section ensures that the user of the amplifier receives haptic feedback (the knob clicking) and/or audible feedback (the clicking sound) when the control knob enters or exists the off/0 position.

The control knob 14₁, 14₂, 14₃ having the OFF position for the drive section 12₁, for the reverb section 12₂ and for the tremolo section 12₃ operate in a slightly different manners. Specifically, when the control knob 14₂, 14₃ for the reverb or tremolo sections 12₂, 12₃ are turned off, the entire section of the amp associated with that control knob (reverb or tremolo or both) is turned off. However, when the control knob 14₁ of the drive section 12₁ is turned OFF, only the drive pre-amp is turned off (and not the entire drive section 12₁).

The foregoing description, for purpose of explanation, has been with reference to specific embodiments. However, the illustrative discussions above are not intended to be exhaustive or to limit the disclosure to the precise forms disclosed. Many modifications and variations are possible in view of the above teachings. The embodiments were chosen and described in order to best explain the principles of the disclosure and its practical applications, to thereby enable others skilled in the art to best utilize the disclosure and various embodiments with various modifications as are suited to the particular use contemplated.

The system and method disclosed herein may be implemented via one or more components, systems, servers, appliances, other subcomponents, or distributed between such elements. When implemented as a system, such systems may include and/or involve, inter alia, components such as software modules, general-purpose CPU, RAM, etc. found in general-purpose computers. In implementations where the innovations reside on a server, such a server may include or involve components such as CPU, RAM, etc., such as those found in general-purpose computers.

Additionally, the system and method herein may be achieved via implementations with disparate or entirely different software, hardware and/or firmware components, beyond that set forth above. With regard to such other components (e.g., software, processing components, etc.) and/or computer-readable media associated with or embodying the present inventions, for example, aspects of the innovations herein may be implemented consistent with numerous general purpose or special purpose computing systems or configurations. Various exemplary computing systems, environments, and/or configurations that may be suitable for use with the innovations herein may include, but are not limited to: software or other components within or embodied on personal computers, servers or server computing devices such as routing/connectivity components, hand-held or laptop devices, multiprocessor systems, microprocessor-based systems, set top boxes, consumer electronic devices, network PCs, other existing computer platforms, distributed computing environments that include one or more of the above systems or devices, etc.

In some instances, aspects of the system and method may be achieved via or performed by logic and/or logic instructions including program modules, executed in association with such components or circuitry, for example. In general, program modules may include routines, programs, objects, components, data structures, etc. that perform particular tasks or implement particular instructions herein. The inventions may also be practiced in the context of distributed software, computer, or circuit settings where circuitry is connected via communication buses, circuitry or links. In distributed settings, control/instructions may occur from both local and remote computer storage media including memory storage devices.

The software, circuitry and components herein may also include and/or utilize one or more type of computer readable media. Computer readable media can be any available media that is resident on, associable with, or can be accessed by such circuits and/or computing components. By way of example, and not limitation, computer readable media may comprise computer storage media and communication media. Computer storage media includes volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical storage, magnetic tape, magnetic disk storage or other magnetic storage devices, or any other medium which can be used to store the desired information and can accessed by computing component. Communication media may comprise computer readable instructions, data structures, program modules and/or other components. Further, communication media may include wired media such as a wired network or direct-wired connection, however no media of any such type herein includes transitory media. Combinations of the any of the above are also included within the scope of computer readable media.

In the present description, the terms component, module, device, etc. may refer to any type of logical or functional software elements, circuits, blocks and/or processes that may be implemented in a variety of ways. For example, the functions of various circuits and/or blocks can be combined with one another into any other number of modules. Each module may even be implemented as a software program stored on a tangible memory (e.g., random access memory, read only memory, CD-ROM memory, hard disk drive, etc.) to be read by a central processing unit to implement the functions of the innovations herein. Or, the modules can comprise programming instructions transmitted to a general-purpose computer or to processing/graphics hardware via a transmission carrier wave. Also, the modules can be implemented as hardware logic circuitry implementing the functions encompassed by the innovations herein. Finally, the modules can be implemented using special purpose instructions (SIMD instructions), field programmable logic arrays or any mix thereof which provides the desired level performance and cost.

As disclosed herein, features consistent with the disclosure may be implemented via computer-hardware, software, and/or firmware. For example, the systems and methods disclosed herein may be embodied in various forms including, for example, a data processor, such as a computer that also includes a database, digital electronic circuitry, firmware, software, or in combinations of them. Further, while some of the disclosed implementations describe specific hardware components, systems and methods consistent with the innovations herein may be implemented with any combination of hardware, software and/or firmware. Moreover, the above-noted features and other aspects and principles of the innovations herein may be implemented in various environments. Such environments and related applications may be specially constructed for performing the various routines, processes and/or operations according to the invention or they may include a general-purpose computer or computing platform selectively activated or reconfigured by code to provide the necessary functionality. The processes disclosed herein are not inherently related to any particular computer, network, architecture, environment, or other apparatus, and may be implemented by a suitable combination of hardware, software, and/or firmware. For example, various general-purpose machines may be used with programs written in accordance with teachings of the invention, or it may be more convenient to construct a specialized apparatus or system to perform the required methods and techniques.

Aspects of the method and system described herein, such as the logic, may also be implemented as functionality programmed into any of a variety of circuitry, including programmable logic devices (“PLDs”), such as field programmable gate arrays (“FPGAs”), programmable array logic (“PAL”) devices, electrically programmable logic and memory devices and standard cell-based devices, as well as application specific integrated circuits. Some other possibilities for implementing aspects include: memory devices, microcontrollers with memory (such as EEPROM), embedded microprocessors, firmware, software, etc. Furthermore, aspects may be embodied in microprocessors having software-based circuit emulation, discrete logic (sequential and combinatorial), custom devices, fuzzy (neural) logic, quantum devices, and hybrids of any of the above device types. The underlying device technologies may be provided in a variety of component types, e.g., metal-oxide semiconductor field-effect transistor (“MOSFET”) technologies like complementary metal-oxide semiconductor (“CMOS”), bipolar technologies like emitter-coupled logic (“ECL”), polymer technologies (e.g., silicon-conjugated polymer and metal-conjugated polymer-metal structures), mixed analog and digital, and so on.

It should also be noted that the various logic and/or functions disclosed herein may be enabled using any number of combinations of hardware, firmware, and/or as data and/or instructions embodied in various machine-readable or computer-readable media, in terms of their behavioral, register transfer, logic component, and/or other characteristics. Computer-readable media in which such formatted data and/or instructions may be embodied include, but are not limited to, non-volatile storage media in various forms (e.g., optical, magnetic or semiconductor storage media) though again does not include transitory media. Unless the context clearly requires otherwise, throughout the description, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list and any combination of the items in the list.

Although certain presently preferred implementations of the invention have been specifically described herein, it will be apparent to those skilled in the art to which the invention pertains that variations and modifications of the various implementations shown and described herein may be made without departing from the spirit and scope of the invention. Accordingly, it is intended that the invention be limited only to the extent required by the applicable rules of law.

While the foregoing has been with reference to a particular embodiment of the disclosure, it will be appreciated by those skilled in the art that changes in this embodiment may be made without departing from the principles and spirit of the disclosure, the scope of which is defined by the appended claims.

What is claimed is:

1. An amplifier, comprising:
a body having one or more speakers housed in the body and an electronic circuit connected to the one or more speakers that controls the sound generated by the one or more speakers;
the body having a control portion, the control portion having one or more control sections and each control section having a plurality of control knobs that control the operation of the electronic circuit; and
a first control knob of the plurality of control knobs in each control section having an off position wherein the first control knob clicks when entering or exiting the off position.

2. The amplifier of claim 1, wherein the control portion has a “0” adjacent each first control knob that indicates that the first control knob is in the off position.

3. The amplifier of claim 2, wherein the one or more control sections further comprises a tremolo control section having an intensity control knob that adjusts an intensity of a tremolo sound effect and a speed control knob that adjusts a speed of the tremolo sound effect, wherein the intensity control knob has the off position.

4. The amplifier of claim 3, wherein the one or more control sections further comprises a drive control section having a drive control knob that adjusts a drive of a preamplifier that is part of the electronic circuitry, a volume control knob that adjusts a volume of the sound generated by the one or more speakers, a treble control knob that adjust a high frequency range of sound generated by the one or more speakers, a middle control knob to adjust a middle frequency range of sound generated by the one or more speakers and a bass control knob that adjusts a low frequency range of sound generated by the one or more speakers, wherein the drive control knob has the off position.

5. The amplifier of claim 4, wherein the one or more control sections further comprises a reverb control section having a jack control knob that adjusts a reverb sound effect, a dwell control knob that adjusts a dwell of the reverb sound effect, a treble control knob that adjust a high frequency range of sound of the reverb sound effect and a bass control knob that adjusts a low frequency range of sound of the reverb sound effect, wherein the jack control knob has the off position.

6. The amplifier of claim 1, wherein the control portion has a jack into which a musical instrument is plugged.

7. The amplifier of claim 1, wherein the first control knob is a leftmost positioned control knob in each control section.

8. The amplifier of claim 1, wherein the first control knob mechanically and audibly clicks when entering or exiting the off position.

9. The amplifier of claim 1, wherein the first control knob is adjustable between a 0 value and a 10 value.

10. The amplifier of claim 5, wherein the drive control knob turns a drive preamplifier off when the drive control know is in the off position.

11. The amplifier of claim 5, wherein the intensity control knob turns off the tremolo control section when the intensity control knob is in the off position and the jack control knob turns off reverb control section when the jack control knob is in the off position.
